(19) United States
(12) Patent Application Publication
(10) Pub. No.: US 2023/0397406 A1
(43) Pub. Date: Dec. 7, 2023

(54) MEMORY DEVICE HAVING CONTROL GATE DIELECTRIC STRUCTURE WITH DIFFERENT DIELECTRIC MATERIALS

(71) Applicant: Micron Technology, Inc, Boise, ID (US)

(72) Inventors: Sau Ha Cheung, Boise, ID (US); Soichi Sugiura, Bristow, VA (US); Jaydip Guha, Boise, ID (US); Anthony J. Kanago, Boise, ID (US); Richard Beeler, Boise, ID (US)

(21) Appl. No.: 17/848,107

(22) Filed: Jun. 23, 2022

Related U.S. Application Data
(60) Provisional application No. 63/347,646, filed on Jun. 1, 2022.

(51) Int. Cl. H01L 27/108

(52) U.S. Cl. CPC H01L 27/10823; H01L 27/10876

(57) ABSTRACT

Some embodiments include apparatuses and methods of forming the apparatuses. One of the apparatuses includes a recess formed in a semiconductor material; a dielectric structure formed in the recess; and a control gate for a transistor of a memory cell, the control gate including a first conductive portion formed in the recess and separated from the semiconductor material by a first portion of the dielectric structure, the first dielectric portion including a first dielectric material between the semiconductor material and the second dielectric material, and a second dielectric material between the first dielectric material and the first conductive portion; and the control gate including the second conductive portion formed over the first conductive portion and separated from the semiconductor material by a second portion of the dielectric structure between the semiconductor material and second conductive portion.

### PRIORITY APPLICATION

This application claims the benefit of priority to U.S. Provisional Application Ser. No. 63/347,646, filed Jun. 1, 2022, which is incorporated herein by reference in its entirety.

### FIELD

Embodiments described herein relate to gate dielectric structures for control gates for transistors of memory cells in memory devices.

### BACKGROUND

Memory devices, such as dynamic random-access memory (DRAM) devices, have memory cells to store information and control gates for controlling access to the memory cells. A control gate has a gate dielectric (often called gate oxide) to electrically isolate the control gate from adjacent structures of the memory cell. The gate dielectric is conventionally formed from silicon dioxide. As features of the memory device get smaller to in part to increase memory cell density for a given area, the thickness of the gate dielectric also gets smaller. However, at a certain dimension, a thinner conventional silicon-dioxide gate dielectric can exceed a lower limit for acceptable reliability of the memory device. This can result in unreliable device performance and longevity.

### BRIEF DESCRIPTION OF THE DRAWINGS

FIG. 1 shows an apparatus in the form of a memory device, according to some embodiments described herein.

FIG. 2 shows a schematic of a memory device having memory cells and control gates for the memory cells, according to some embodiments described herein.

FIG. 3A and FIG. 3B show different views of a structure of a portion of the memory device of FIG. 2, according to some embodiments described herein.

FIG. 3C, FIG. 3D, and FIG. 3E show the same view as FIG. 3B with additional labels added to some of the elements shown in FIG. 3B, according to some embodiments described herein.

FIG. 4 through FIG. 13 show different views of structures during processes of forming the memory device of FIG. 2 through FIG. 3E, according to some embodiments described herein.

### DETAILED DESCRIPTION

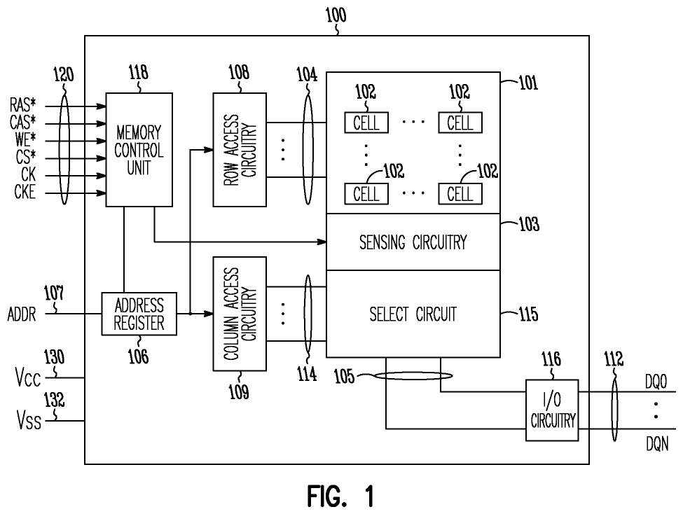

The techniques described herein involve a memory device having memory cells and control gates and gate dielectric structures for transistors (e.g., access transistors) of the memory cells. The control gates can be part of access lines (e.g., word lines) of the memory device. As mentioned above, as features of the memory device get smaller, a conventional silicon-dioxide gate dielectric is limited to a certain small thickness. The gate dielectric structure described herein can include different dielectric materials including a high-k dielectric material. The high-k dielectric material included in the described gate dielectric structure allows the gate dielectric structure to overcome the thickness limitation of conventional silicon-dioxide gate dielectric and maintain or achieve an improved (e.g., increased) drive capability for the access transistor. This allows the transistor including the gate dielectric structure to be implemented in a technology at smaller scale. Other improvements and benefits of the described techniques are further discussed below with reference to FIG. 1 through FIG. 13.

FIG. 1 shows a block diagram of an apparatus in the form of a memory device 100 including volatile memory cells, according to some embodiments described herein. Memory device 100 includes a memory array 101, which can contain memory cells 102. Memory device 100 can include a volatile memory device such that memory cells 102 can be volatile memory cells. An example of memory device 100 includes a dynamic random-access memory (DRAM) device. Information stored in memory cells 102 of memory device 100 may be lost (e.g., invalid) if supply power (e.g., supply voltage Vcc) is disconnected from memory device 100. Hereinafter, supply voltage Vcc is referred to as representing some voltage levels; however, they are not limited to a supply voltage (e.g., Vcc) of the memory device (e.g., memory device 100). For example, if the memory device (e.g., memory device 100) has an internal voltage generator (not shown in FIG. 1) that generates an internal voltage based on supply voltage Vcc, such an internal voltage may be used instead of supply voltage Vcc.

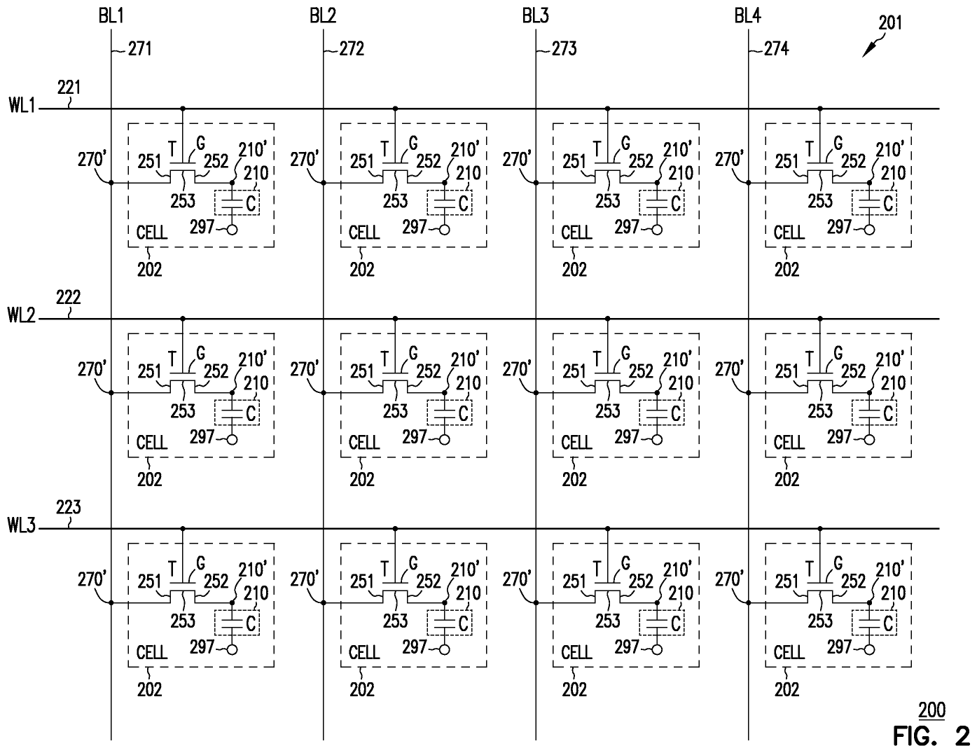

In a physical structure of memory device 100, each of memory cells 102 can include a transistor and a storage element (store device). The storage element can include a capacitor or other storage elements different from a capacitor. The structure of memory array 101, including memory cells 102, can include the structure of memory arrays and memory cells described below with reference to FIG. 2 through FIG. 13.

As shown in FIG. 1, memory device 100 can include access lines 104 (e.g., “word lines”) and data lines (e.g., bit lines) 105. Memory device 100 can use signals (e.g., word line signals) on access lines 104 to access memory cells 102 and data lines 105 to provide information (e.g., data) to be stored in (e.g., to be written to or programed in) or read (e.g., sensed) from memory cells 102.

Memory device 100 can include an address register 106 to receive address information ADDR (e.g., row address signals and column address signals) on lines 107 (e.g., address lines). Memory device 100 can include row access circuitry 108 (e.g., X-decoder) and column access circuitry 109 (e.g., Y-decoder) that can operate to decode address information ADDR from address register 106. Based on decoded address information, memory device 100 can determine which memory cells 102 are to be accessed during a memory operation. Memory device 100 can perform a write operation to store information in memory cells 102, and a read operation to read (e.g., sense) information (e.g., previously stored information) in memory cells 102. Memory device 100 can also perform an operation (e.g., a refresh operation) to refresh (e.g., to keep valid) the value of information stored in memory cells 102. Each of memory cells 102 can be configured to store information that can represent at most one bit (e.g., a single bit having a binary 0 (“0”) or a binary 1 (“1”), or more than one bit (e.g., multiple bits having a combination of at least two binary bits).

Memory device 100 can receive a supply voltage, including supply voltages Vcc and Vss, on lines 130 and 132, respectively. Supply voltage Vss can operate at a ground potential (e.g., having a value of approximately zero volts). Supply voltage Vcc can include an external voltage supplied to memory device 100 from an external power source such as a battery or an alternating current to direct current (AC-DC) converter circuitry.

As shown in FIG. 1, memory device 100 can include a memory control unit 118, which includes circuitry (e.g., hardware components) to control memory operations (e.g., read and write operations) of memory device 100 based on control signals on lines (e.g., control lines) 120. Examples of signals on lines 120 include a row access strobe signal RAS*, a column access strobe signal CAS*, a write-enable signal WE*, a chip select signal CS*, a clock signal CK, and a clock-enable signal CKE. These signals can be part of signals provided to a DRAM device.

As shown in FIG. 1, memory device 100 can include lines (e.g., global data lines) 112 that can carry signals DQ0 through DQN. In a read operation, the value (e.g., “0” or “1”) of information (read from memory cells 102) provided to lines 112 (in the form of signals DQ0 through DQN) can be based on the values of the signals on data lines 105. In a write operation, the value (e.g., “0” or “1”) of information provided to data lines 105 (to be stored in memory cells 102) can be based on the values of signals DQ0 through DQN on lines 112.

Memory device 100 can include sensing circuitry 103, select circuitry 115, and input/output (I/O) circuitry 116. Column access circuitry 109 can selectively activate signals on lines (e.g., select lines) based on address signals ADDR. Select circuitry 115 can respond to the signals on lines 114 to select signals on data lines 105. The signals on data lines 105 can represent the values of information to be stored in memory cells 102 (e.g., during a write operation) or the values of information read (e.g., sensed) from memory cells 102 (e.g., during a read operation).

I/O circuitry 116 can operate to provide information read from memory cells 102 to lines 112 (e.g., during a read operation) and to provide information from lines 112 (e.g., provided by an external device) to data lines 105 to be stored in memory cells 102 (e.g., during a write operation). Lines 112 can include nodes within memory device 100 or pins (or solder balls) on a package where memory device 100 can reside. Other devices external to memory device 100 (e.g., a hardware memory controller or a hardware processor) can communicate with memory device 100 through lines 107, 112, and 120.

Memory device 100 may include other components, which are not shown in FIG. 1 so as not to obscure the example embodiments described herein. At least a portion of memory device 100 (e.g., a portion of memory array 101) can include structures and operations similar to or the same as any of the memory devices described below with reference to FIG. 2 through FIG. 13.

FIG. 2 shows a schematic diagram of a portion of a memory device 200 including a memory array 201, according to some embodiments described herein. Memory device 200 can correspond to memory device 100 of FIG. 1. For example, memory array 201 can form part of memory array 101 of FIG. 1. As shown in FIG. 2, memory device 200 can include memory cells 202, data lines (e.g., bit lines) 271, 272, 273, and 274, and access lines (e.g., word lines) 221, 222, and 223. For simplicity, FIG. 2 shows 12 memory cells 202, four data lines 271, 272, 273, and 274, and three access lines 221, 222, and 223. However, memory device 200 can include numerous memory cells, data lines, and access lines.

Memory cells 202 include volatile memory cells (e.g., DRAM cells). For simplicity, similar or identical elements among memory cells 202 are given the same labels. Each of memory cells 202 can include transistor T (e.g., access transistor) and a charge storage structure (e.g., memory element) 210. Transistor T can include a field-effect transistor (FET). As an example, transistor T can be an n-channel FET (NFET). Thus, transistor T can include an operation similar to that of an n-channel metal-oxide semiconductor (NMOS) transistor. Alternatively, transistor T can be a p-channel FET (PFET) that can include an operation similar to that of a p-channel metal-oxide semiconductor (PMOS) transistor.

FIG. 2 shows charge storage structure 210 including a capacitor C as an example. However, charge storage structure 210 can include another type of storage element different from a capacitor. As shown in FIG. 2, charge storage structure 210 can be coupled to transistor T (e.g., coupled to drain 252 of transistor T) through a conductive contact (e.g., capacitor contact) 210′. Charge storage structure 210 can also be coupled to a node 297. Node 297 can be part of a ground connection memory device 200. Alternatively, node 297 can be coupled to voltage source different from ground. In the example of FIG. 2, capacitor C can include one terminal (e.g., a capacitor plate) coupled to conductive contact 210′ and another terminal (e.g., another capacitor plate) coupled to node 297. Charge storage structure 210 can form the memory element of a respective memory cell among memory cells 202. Charge storage structure 210 can store charge. The value (e.g., “0” or “1”) of information stored in a particular memory cell among memory cells 202 can be based on the amount of charge stored in charge storage structure 210 (e.g., stored in capacitor C) of that particular memory cell.

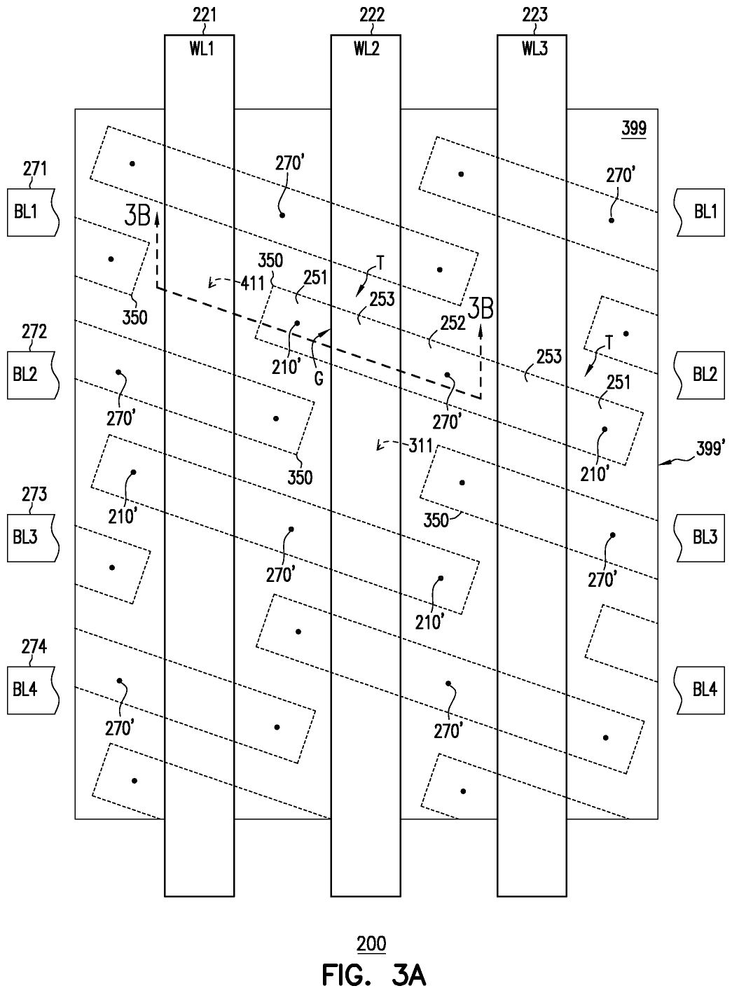

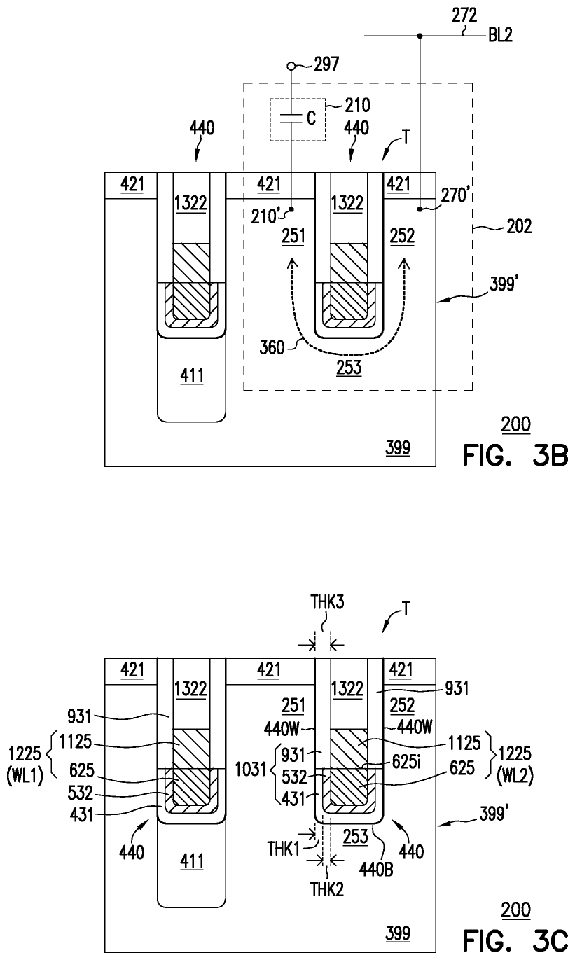

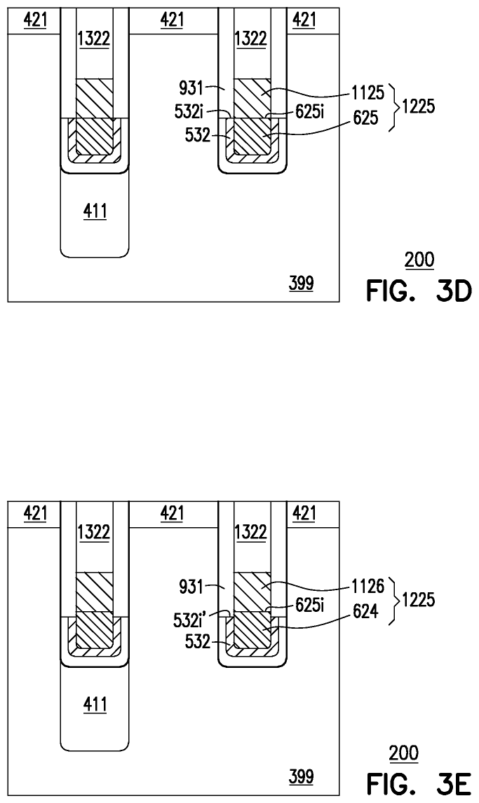

As shown in FIG. 2, transistor T can include a control gate G and regions (e.g., source and drain regions) 251 and 252. In this description, source and drain are used interchangeably. Thus, region 251 can be called source 251 region of transistor T and region 252 can be called drain 252 of transistor T. Alternatively, region 251 can be called drain 251 region of transistor T and region 252 can be called source 252 of transistor T. As shown in FIG. 2, transistor T can also include a channel 253 between source and drain 251 and 252. In operation, a current can flow in a circuit path (e.g., current path) 360 (labeled in FIG. 3B) between drains 251 and 252 through channel 253.

Data lines 271, 272, 273, and 274 (which can include bit lines) can carry respective signals (e.g., bit line signals) BL1, BL2, BL3, and BL4. Each memory cell 202 can be coupled to a respective data line among data lines (e.g., bit lines) 271, 272, 273, and 274 through a conductive contact (e.g., bit line contact) 270′. Conductive contact 270′ can be coupled to drain 252 of a respective transistor T. During a read operation, memory device 200 can use data line 270 to obtain information read (e.g., sensed) from a selected memory cell 202. During a write operation, memory device 200 can use data line 270 to provide information to be stored in a selected memory cell 202. During an operation (e.g., read or write operation) of memory device 200, a circuit path (e.g., current path) can be formed between a respective data line 270 and charge storage structure 210 of a particular memory cell (e.g., a selected memory cell 202) through source, drain, and channel 251, 252, and 253, respectively, of transistor T of the particular memory cell.

Access lines 221, 222, and 223 (which can include word lines) can carry respective signals (e.g., word line signals) WL1, WL2, and WL3. Memory device 200 can use access lines 221, 222, and 223 to selectively access memory cells 202 (selected memory cells 202). Control gates G of different transistors T in a row (e.g., four transistors T in the same row from left to right in FIG. 2) can be coupled to (e.g., can share) the same access line associated with that row. In a physical structure of memory device 200, access lines 221, 222, and 223 are structured as a conductive line that includes conductive structure. Control gate G of a respective transistor T is part of (a portion of) the conductive structure of a respective access line, as described in more detail with reference to FIG. 3A through FIG. 3E.

FIG. 3A and FIG. 3B show different views of a structure of a portion of memory device 200 of FIG. 2, according to some embodiments described herein. FIG. 3C, FIG. 3D, and FIG. 3E show the same view as FIG. 3B. However, to avoid crowding in FIG. 3B, additional labels are added to the elements of FIG. 3C, FIG. 3D, and FIG. 3E that are also shown in FIG. 3B but without labels in FIG. 3B.

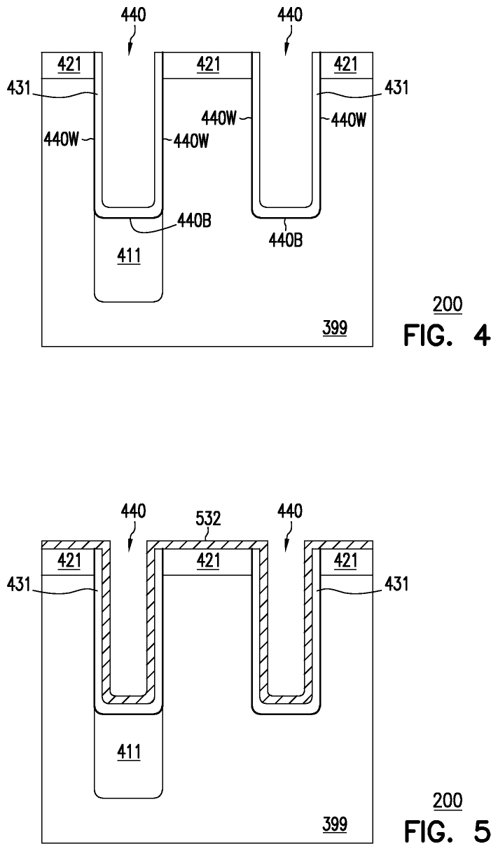

For simplicity, cross-sectional lines (e.g., hatch lines) are omitted from most of the elements shown in FIG. 3A, FIG. 3B, FIG. 3C, FIG. 3D, and FIG. 3E and other figures (e.g., FIG. 4 through FIG. 13) in the drawings described herein. Some elements of memory device 200 may be omitted from a particular figure of the drawings so as to not obscure the description of the element (or elements) being described in that particular figure. The dimensions (e.g., physical structures) of the elements shown in the drawings described herein are not scaled.

FIG. 3A shows a top view (e.g., a layout) of a structure of a portion of memory device 200 (schematically shown in FIG. 2). FIG. 3B shows a side view (e.g., a cross-section) of memory device 200 along line (e.g., sectional line) 3B-3B of FIG. 3A. FIG. 3C shows the same view as FIG. 3B without charge storage structure 210, data line 272 and with additional labels for the structure of transistor T and labels for a conductive structure of access line 222 (associated with signal WL2). FIG. 3D shows the same view as FIG. 3C with the addition of labels for interfaces 532i and 625i. FIG. 3E shows an alternative structure of memory device 200 of FIG. 3 including a position of an interface 532i′ relative to an interface 625i.

As shown in FIG. 3A, memory device 200 can include a substrate 399, regions (active regions) 350 formed in substrate 399, and isolation structures 311 formed in substrate 399. Substrate 399 can include a semiconductor substrate (e.g., a silicon-based substrate). Each region 350 can be doped regions in the material 399′ in substrate 399. Material 399′ can include semiconductor material (e.g., a silicon or silicon-based material) or other conductive materials. Isolation structures 311 can include dielectric material (e.g., silicon dioxide) formed between adjacent regions 350 to electrically isolate regions 350 from each other. An example of isolation structures 311 include shallow trench isolation (STI) structures.

FIG. 3A partially shows the structure of data lines 271, 272, 273, and 274 for ease of viewing other elements of memory device 200 formed under (below) shows data lines 271, 272, 273, and 274. Data lines 271, 272, 273, and 274 can have respective lengths extending in a direction (e.g., from left to right in FIG. 3A) perpendicular to the lengths of access lines 221, 222, and 223. Data lines 271, 272, 273, and 274 are formed in a level (physical level) of memory device 200 that is over the level (physical level) of access lines 221, 222, and 223.

As shown in FIG. 3A, regions 350 can be formed in material 399 of substrate 399 such that they can be at slanted positions with respect to the lengths of access lines 221, 223, and 223. Each region 350 can include source, drain, and channel 251, 252, and 253, respectively, of two transistors T (adjacent transistors T) of two respective memory cells 202 (not labeled in FIG. 3A). Drain 252 in a particular region 350 can be shared by the two adjacent transistors T in that particular region 350.

FIG. 3A also shows conductive contacts 210′ coupled to respective regions 350. For simplicity, FIG. 3A omits labels for some of conductive contacts 210′. Each conductive contact 210′ can be coupled to source 252 of a respective transistor T and a respective capacitor C (as described above with reference to FIG. 2). For simplicity, FIG. 3A does not show capacitors Cs of memory cells 202.

FIG. 3A also shows conductive contacts (e.g., bit line contacts) 270′ coupled to respective regions 350. Each conductive contact can be coupled to drain 252 of a respective transistor T and to a respective data line among data lines 271, 272, 273, and 274 (as described above with reference to FIG. 2)

As shown in FIG. 3A, each access line 221, 222, or 223 can extend through respective regions 350 and respective isolation structures 311. Control gate G of a particular transistor T can be part of a respective access line over (e.g., directly over) channel 253 of that a particular transistor T.

As shown in FIG. 3A, line 3B-3B cuts through a portion of access line 221 formed in isolation structures 311, and a portion of access line 222 (e.g., control gate G of transistor T) formed in a portion of region 350.

As shown in FIG. 3B, source, drain, and channel 251, 252, and 253, respectively, can be included in (e.g., formed in) respective portions of material 399′ of substrate 399. The portions that include source, drain, and channel 251, 252, and 253, respectively, can be included in region 350 (labeled in FIG. 3A). FIG. 3B also shows conductive path (e.g., current path) 360 between source 251 and drain 252 through channel 253 that can be created during an operation (e.g., a read or write operation) of memory device 200.

In FIG. 3B, conductive contact 210′ (coupled to charge storage structure 210) can be formed such that it can contact (e.g., directly coupled to) the portion of material 399′ where source 251 is located. Conductive contact 270′ (coupled to data line 272) can be formed such that it can contact (e.g., directly coupled to) the portion of material 399′ where drain 252 is located. For simplicity, charge storage structure 210 (which can include capacitor C), data line 272, and conductive contacts 210′ and 270′ are schematically (instead of structurally) shown in FIG. 3B.

As shown in FIG. 3B, memory device 200 can include recesses 440 formed in material (e.g., semiconductor material) 399′ of substrate 399. Each recess 440 can be a trench formed in material 399′ of substrate 399 such that substrate 399 is void of the material 339′ in each recess 440. FIG. 3B also shows the location of isolation structure 411 (under the access line associated with signal WL1 in FIG. 3A).

FIG. 3C shows a cross-section of a conductive structure 1225 formed in a respective recess 440. Conductive structure 1225 can include a conductive portion 625 and a conductive portion 1125 formed in recess 440. Conductive portion 1125 can be formed over (e.g., formed on) conductive portion 625 in recess 440. Conductive structure 1225 is part of a respective access line (e.g., word line associated with signal WL1 or WL2). Conductive structure 1225 can form control gate G of transistor T. Thus, control gate G of transistor T can include conductive portions 625 and 1125 of conductive structure 1225. Conductive structure 1225 (both conductive portions 625 and 1125) can extend (e.g., run) continuously along the length of a respective access line.

As shown in FIG. 3C, source 251 of transistor T can be a portion of material 399′ on one side (e.g., left side) of a conductive structure 1225. Drain 252 of transistor T can be a portion of material 399′ on another side (e.g., right side) of conductive structure 1225 opposite from the side where source 251 is located. Channel 253 can be a portion of material 399′ on another side (e.g., bottom side) of conductive structure 1225.

Memory device 200 can include a dielectric structure 1031, which can form (e.g., is part of) a gate dielectric structure (e.g., gate oxide) associated with control gate G (FIG. 2 and FIG. 3A) of transistor T of a respective memory cell 202 (FIG. 2). As shown in FIG. 3C, dielectric structure (e.g., gate dielectric structure) 1031 can be a relatively thin dielectric liner formed on sidewalls 440W and on a bottom 440B of recess 440. As shown in FIG. 3C, dielectric structure 1031 can be formed such that a cross-section of dielectric structure 1031 can have a “U” shape (e.g., a dielectric liner having a “U” shape).

Dielectric structure 1031 can include a portion (e.g., a lower portion) that includes a dielectric material 431 and a dielectric material 532. Dielectric structure 1031 can include a portion (e.g., an upper portion) that includes a dielectric material 931. Thus, as shown in FIG. 3C, dielectric material 431 and a dielectric material 532 can be included in a lower portion of the “U” shape structure of dielectric structure 1031. Dielectric material 931 can be included in an upper portion of the “U” shape structure of dielectric structure 1031.

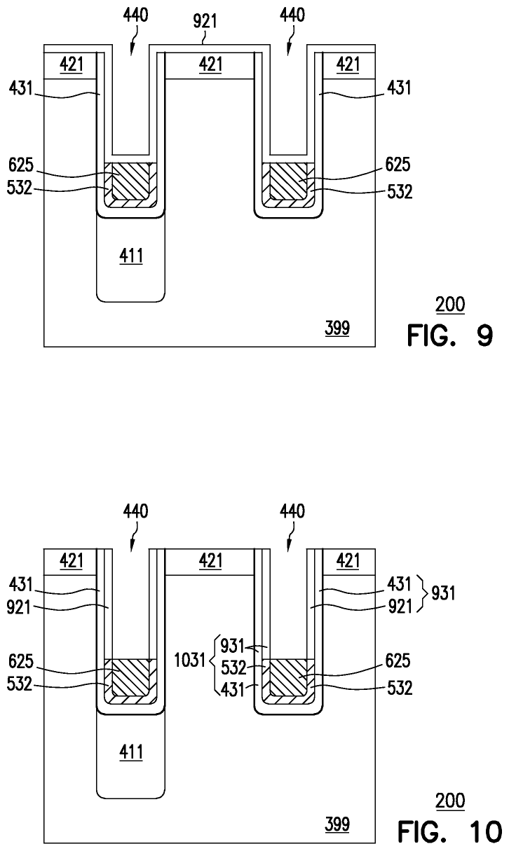

Although FIG. 3C shows dielectric material 931 being a single piece of dielectric material, dielectric material 931 can include two layers of the same dielectric material (e.g., two layers of silicon dioxide). For example, dielectric material 931 can be formed from the processes described below with reference to FIG. 4 through FIG. 13, such that dielectric material 931, as shown in FIG. 9, can be a combination (e.g., two layers) of a dielectric material (e.g., silicon dioxide) 921 (FIG. 9) and dielectric material (e.g., silicon dioxide) 431 (FIG. 9).

In FIG. 3C, dielectric material 532 can be different from dielectric material 431 and dielectric material 931. Dielectric materials 431 and 931 can include the same material. For example, each of dielectric materials 431 and 931 can include (e.g., can be formed from) silicon dioxide. Thus, dielectric materials 431 and 931 can have the same dielectric constant. Dielectric materials 931 can have a dielectric constant less than the dielectric constant of dielectric material 532.

Dielectric material 532 can include a high-k dielectric material. A high-k dielectric material is a dielectric material that has a dielectric constant greater than the dielectric constant of silicon dioxide. Thus, dielectric material 532 can be different from silicon dioxide. In an example, dielectric material 431 can include silicon dioxide, and dielectric material 532 can have a dielectric constant greater than the dielectric constant of silicon dioxide.

Examples of dielectric materials 532 include aluminum oxide, yttrium oxide, zirconium oxide, hafnium oxide, strontium oxide, and an oxide including elements from lanthanide series (e.g., lanthanum oxide and lutetium oxide), or other high-k dielectric material.

As shown in FIG. 3C, dielectric material 431 can have a thickness TKH1. Dielectric material 532 can have thickness THK2. Dielectric material 931 can have thickness THK3. Thicknesses THK1 and THK2 can be equal (e.g., substantially equal) to each other. Alternatively, thicknesses THK1 and THK2 can be unequal to each other. For example, thickness THK1 can be less than (or greater than) thickness THK2.

Each of thicknesses THK1 and THK2 is less than thickness THK3. For example, thickness THK1 can be equal to one-half (or less than one-half) of thickness THK3. In another example, thickness THK1 can be greater than one-half of thickness THK3 and less than thickness THK3.

As an example, thickness THK2 can be equal to one-half (or less than one-half) of thickness THK3. In another example, thickness THK2 can be greater than one-half of thickness THK3 and less than thickness THK3.

The sum of the thicknesses THK1 and THK2 can be at most equal to (not greater than) thickness THK3. Alternatively, the sum of the thicknesses THK1 and THK2 can be greater than thickness THK3.

Thicknesses THK1, THK2, and THK3 can be measured in nanometer units. For example, each of thicknesses THK1 and THK2 can be 2 nanometers. However, each of thicknesses THK1 and THK2 can have a different value. For example, the value of each of thicknesses THK1 and THK2 can be in a range from 1.5 nanometers to 2.5 nanometers.

In an example, thicknesses THK3 can be 4 nanometers. However, thicknesses THK3 can have a different value. For example, the value of thickness THK3 can be in a range from 3 nanometers to 5 nanometers.

As shown in FIG. 3C, the sides (e.g., opposing left and right sides and bottom side) of conductive structure 1225 (which form control gate G of transistor T) can be surrounded by the “U” shape structure of dielectric structure (e.g., gate dielectric structure) 1031 to electrically isolate conductive structure 1225 (conductive portions 625 and 1125) from material (e.g., semiconductor material) 399′. As described above, dielectric structure 1031 can have different dielectric materials, including dielectric material (e.g., silicon dioxide) 431 and dielectric material (e.g., high-k dielectric material) 532 in a lower portion of dielectric structure 1031, and dielectric material (e.g., silicon dioxide) 931 in an upper portion of dielectric structure 1031.

Conductive portion 625 is separated from material (e.g., semiconductor material) 399′ of substrate 399 by a portion (e.g., lower portion) of dielectric structure 1031 that include dielectric materials 431 and 532. As shown in FIG. 3C, dielectric material 431 is between (e.g., contacting) material 399′ and dielectric material 532. Dielectric material 532 is between (e.g., contacting) dielectric material 431 and conductive portion 625.

Conductive portion 1125 is separated from material (e.g., semiconductor material) 399′ of substrate 399 by a portion (e.g., upper portion) of dielectric structure 1031 that include dielectric material 931. As shown in FIG. 3C, dielectric material 931 is between (e.g., contacting) material 399′ and conductive portion 1125.

Conductive portions 625 and 1125 of conductive structure 1225 can include different conductive materials. For example, conductive portion 625 can include a conductive material, which can include metal, metal-based material, or combinations of different conductive materials. As an example, conductive portion 625 can include tungsten, titanium nitride, other conductive materials, or combination of conductive materials. In another example, conductive portion 1125 can include a conductive material, which can include polysilicon (e.g., conductively doped polysilicon (e.g., N+ polysilicon)), other conductive materials, or a combination of conductive materials.

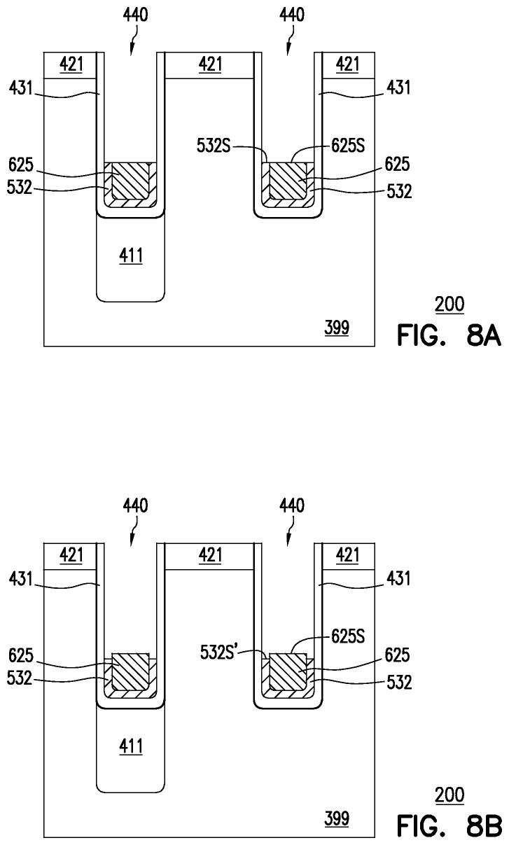

As shown in FIG. 3D, dielectric material 532 can contact dielectric material 931 at an interface 532i. Interface 532i can be the location of a surface (e.g., surface 532S, labeled in FIG. 8A) of dielectric material 532. Conductive portion 625 can contact conductive portion 1125 at an interface 625i. In the structure of memory device 200 of FIG. 3D, interface 532i can be at the same level as the of interface 625i. Interface 625i can be the location of a surface (e.g., surface 625S, labeled in FIG. 8A) of conductive portion 625 that is the same as the location of a surface (e.g., bottom surface, not labeled) of conductive portion 1125. Thus, as shown in FIG. 3D, interface 532i can be at the same level as the level of a surface (e.g., surface 525S, labeled in FIG. 8A) of conductive portion 625 or the same level as the level of a surface (e.g., bottom surface, not labeled) of conductive portion 1125.

FIG. 3E shows an alternative position of an interface between dielectric materials 532 and 931. For example, dielectric material 532 can contact dielectric material 931 at an interface 532i′. Interface 532i′ can be the location of a surface (e.g., surface 532S′ labeled in FIG. 8B) of dielectric material 532. In the structure of memory device 200 of FIG. 3E, interface 532i′ can be at a level below a level of interface 625i. Thus, as shown in FIG. 3E, interface 532i′ can be at a level below a level of a surface (e.g., surface 625, labeled in FIG. 8B) of conductive portion 625 or below a level of a surface (e.g., bottom surface, not labeled) of conductive portion 1125.

The structure of memory cell 202, including differences in dielectric materials and in thicknesses among the dielectric materials of dielectric structure 1031, provides improvements and benefits to memory device 200 in comparison with some conventional memory devices. For example, as mentioned above, a relatively thin silicon-diode gate dielectric can reduce drive capability of an access transistor of a memory cell in a conventional device. Further, a thick silicon-diode gate dielectric can cause excessive charge leakage, leading to reduced device reliability and performance.

In memory device 200, the inclusion of a high-k dielectric material (e.g., dielectric material 532) in dielectric structure (e.g., gate dielectric structure) 1031 can improve (e.g., increase) drive capability of transistor T without reducing the relative thickness of dielectric structure 1031.

Further, the inclusion of dielectric material 532 having thickness THK2 with a value relative to the values of thicknesses THK1 and THK3 (as described above) allows transistor T to maintain or suppress charge leakage at the portion (e.g., lower portion) of dielectric structure 1031 where dielectric material 532 is formed. This allows memory device 200 to maintain or improve reliability in device operation and performance.

Moreover, the inclusion of high-k dielectric material (e.g., dielectric material 532) in a portion (e.g., a lower portion) of dielectric structure 1031 and not in another portion (e.g., upper portion) of dielectric structure 1031 allows dielectric material 931 to be formed with enough thickness (e.g., thickness THK3) at a location that is susceptible to charge leakage. This also allows memory device 200 to further maintain or improve reliability in device operation and performance and longevity.

Additionally, a convention silicon-dioxide gate dielectric is limited to a certain thickness to stay within an acceptable reliability. In memory device 200, the inclusion of dielectric material 532 (which have a relatively small thickness (e.g., thickness THK2)) allows dielectric structure (e.g., gate dielectric structure) 1031 to overcome gate-dielectric thickness limitation of a conventional silicon-dioxide gate dielectric and maintain or achieve an improved (e.g., increased) drive capability for transistor T. This allows transistor T including dielectric structure 1031 to be implemented in a technology at smaller scale.

FIG. 4 through FIG. 13 show different views of structures during processes of forming memory device 200 of FIG. 2 through FIG. 3E, according to some embodiments described herein. The locations of the structure (e.g., side views) of memory device 200 in FIG. 4 through FIG. 13 can correspond to the location (e.g., side view of memory device 200) along line 3B-3B in FIG. 3A.

FIG. 4 shows memory device 200 after isolation structure 411, recesses 440 are formed in material 399′ of substrate 399. FIG. 4 also shows memory device 200 after dielectric material (e.g., silicon dioxide) 421 and dielectric material 431 are formed. Dielectric material 431 can be formed in respective sidewalls 440W and bottoms 440B of recesses 440. Dielectric material 431 can include silicon dioxide. Forming dielectric material dielectric material 431 can be formed by in-situ steam generation (ISSG) process or by chemical oxidation process.

FIG. 5 shows memory device 200 after dielectric material 532 is formed on dielectric material 431 in recesses 440. Dielectric material 431 can be formed by atomic layer deposition (ALD) process. As described above dielectric material 431 can include a high-k dielectric material.

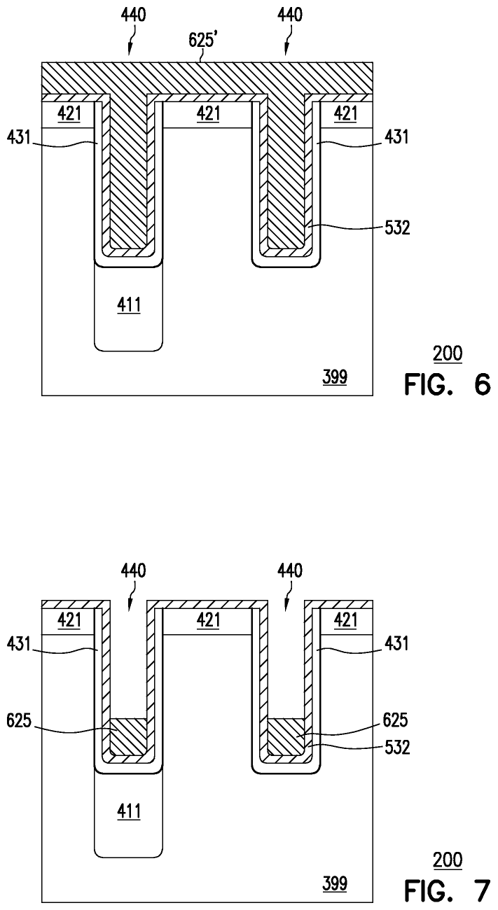

FIG. 6 shows memory device 200 after a conductive material conductive material 625′ is formed (e.g., deposited) in recesses 440. Conductive material 625′ can include metal, metal-based material, or combinations of different conductive materials.

FIG. 7 shows memory device 200 after conductive portion 625 is formed in recesses 440. Forming conductive portion 625 can include removing (e.g., etching) a portion (e.g., top portion) of conductive material 625′ (FIG. 6). Conductive portion 625 in recesses 440 is the remaining portion of conductive material 625′.

FIG. 8A shows memory device 200 after a portion (e.g., top portion) of dielectric material 532 in FIG. 7 is removed. A remaining portion of dielectric material 532 is shown in FIG. 8A. Removing the portion of dielectric material 532 in FIG. 7 can include an etch process such that dielectric material 532 remaining in FIG. 8A can have a surface (e.g., upper surface) 532S. Surface 532S can be at the same level as the level of a surface 625S of conductive portion 625.

FIG. 8B shows an alternative process where a portion (e.g., top portion) of dielectric material 532 can be removed such that dielectric material 532 remaining in FIG. 8B can have a surface (e.g., upper surface) 532S′. As shown in FIG. 8B, surface 532S′ can be at a level below the level of surface 625S of conductive portion 625.

FIG. 9 shows memory device 200 after dielectric material 921 is formed (e.g., deposited) on dielectric material 431 and also formed over dielectric material 532 and 625.

FIG. 10 shows memory device 200 after a portion of dielectric material 921 over conductive portion 625 is removed (e.g., punched through) to expose conductive portion 625 at recesses 440. As shown in FIG. 10, the combination (e.g., two layers) of dielectric material 921 and a portion (e.g., upper portion) of dielectric material 431 can correspond to dielectric material 931 (as described above with reference to FIG. 3C). As shown in FIG. 10, a portion (e.g., lower portion) of dielectric material 431, dielectric material 532, and dielectric material 931 form dielectric structure 1031, which is described in detail above with reference to FIG. 3B through FIG. 3E.

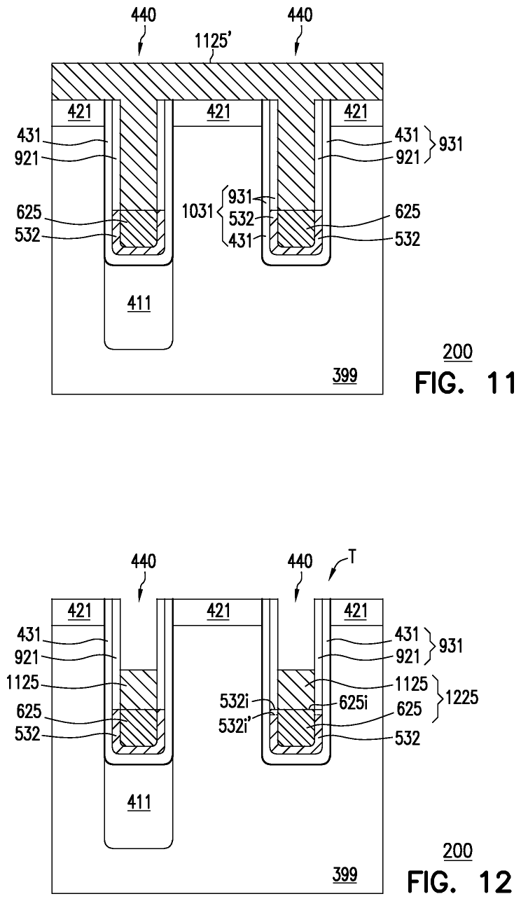

FIG. 11 shows memory device 200 after a conductive material 1125′ is formed (e.g., deposited) in recesses 440 and over (e.g., formed on) conductive portion 625. Conductive material 1125′ can include polysilicon (e.g., conductively doped polysilicon (e.g., N+ polysilicon)), other conductive materials, or a combination of conductive materials.

FIG. 12 shows memory device 200 after conductive portion 1125 is formed in recesses 440. Forming conductive portion 1125 can include removing (e.g., etching) a portion (e.g., top portion) of conductive material 1125′ (FIG. 11). Conductive portion 1125 in recesses 440 is the remaining portion of conductive material 1125′. As shown in FIG. 12, conductive portions 625 and 1125 form conductive structure 1225 of an access line (e.g., word line) which is described in detail with reference to FIG. 3A through FIG. 3E. FIG. 12 also shows interface 625i and interface 532i that are the same as those described above with reference to FIG. 3D. Interface 532i′ is an alternative of interface 532i and is described above with reference to FIG. 3E.

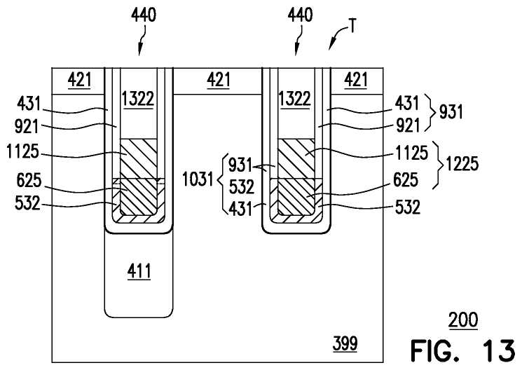

FIG. 13 shows memory device 200 after a dielectric material (silicon nitride) 1322 on 1125 is formed in recesses 440 and over (e.g., formed on) 1125. Dielectric material 1322 can be formed to separate (e.g., electrically isolate) a portion (e.g., top portion) of conductive structure 1225 from other elements of memory device 200.

The process of forming memory device 200 as described above with reference to FIG. 4 through FIG. 13 can include additional processes after the processes associated with FIG. 13 are performed. For example, additional processes can include forming conductive contact (e.g., capacitor contact) 210′ (FIG. 3B), charge storage structure 210 (FIG. 3B), conductive contact (e.g., bit line contact) 270′ (FIG. 3B), data lines (e.g., data lines 271, 272, 273, and 274 in FIG. 3A) and other elements and interconnections to complete the processes of forming memory device 200.

The illustrations of apparatuses (e.g., memory devices 100 and 200) and methods (e.g., methods of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., an electronic item that can include any of memory devices 100 and 200).

Any of the components described above with reference to FIG. 1 through FIG. 13 can be implemented in a number of ways, including simulation via software. Thus, apparatuses (e.g., memory devices 100 and 200), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100 and 200) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 13 include apparatuses and methods of forming the apparatuses. One of the apparatuses includes a recess formed in a semiconductor material; a dielectric structure formed in the recess; and a control gate for a transistor of a memory cell, the control gate including a first conductive portion formed in the recess and separated from the semiconductor material by a first portion of the dielectric structure, the first dielectric portion including a first dielectric material between the semiconductor material and the second dielectric material, and a second dielectric material between the first dielectric material and the first conductive portion; and the control gate including the second conductive portion formed over the first conductive portion and separated from the semiconductor material by a second portion of the dielectric structure between the semiconductor material and second conductive portion. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

In the detailed description and the claims, the terms “first,” “second,” and “third,” etc. are used merely as labels, and are not intended to impose numerical requirements on their objects.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a recess formed in a semiconductor material;
a dielectric structure formed in the recess; and
a control gate for a transistor of a memory cell, the control gate including a first conductive portion and second conductive portion formed in the recess, the first and second conductive portions including different conductive materials, wherein:
the first conductive portion is separated from the semiconductor material by a first portion of the dielectric structure, the first dielectric portion including a first dielectric material between the semiconductor material and the second dielectric material, and a second dielectric material between the first dielectric material and the first conductive portion; and
the second conductive portion is formed over the first conductive portion and is separated from the semiconductor material by a second portion of the dielectric structure between the semiconductor material and second conductive portion.

2. The apparatus of claim 1, wherein the second dielectric material has a dielectric constant greater than a dielectric constant of silicon dioxide.

3. The apparatus of claim 1, wherein:
the first dielectric material includes a first thickness;
the second dielectric material includes a second thickness; and
the second portion of the dielectric structure includes a third thickness, wherein each of the first and second thicknesses is less than the third thickness.

4. The apparatus of claim 3, wherein a sum of the first thickness and the second thickness is not greater than the third thickness.

5. The apparatus of claim 1, wherein the second dielectric material has a dielectric constant greater than a dielectric constant of the first dielectric material.

6. The apparatus of claim 1, wherein the second dielectric material has a dielectric constant greater than a dielectric constant of a material of the second portion of the dielectric structure.

7. The apparatus of claim 1, wherein the second portion of the dielectric structure includes a same dielectric material as the first dielectric material.

8. The apparatus of claim 1, wherein the second conductive portion includes polysilicon.

9. The apparatus of claim 8, wherein the second conductive portion includes a metal material.

10. The apparatus of claim 1, wherein the second dielectric material includes one of aluminum oxide, yttrium oxide, zirconium oxide, hafnium oxide, strontium oxide, and an oxide including elements from lanthanide series.

11. The apparatus of claim 1, wherein the control gate is part of an access line for the memory cell.

12. An apparatus comprising:
a conductive structure formed in material of a memory device and separated from the material of the memory device by a dielectric structure, the conductive structure including a first conductive portion and a second conductive portion formed over the first conductive portion, wherein:
the dielectric structure includes a first dielectric portion between the material of the memory device and the first conductive portion, and the first dielectric portion includes a first dielectric material having a first thickness, and a second dielectric material having a second thickness and a dielectric constant greater than a dielectric constant of silicon dioxide; and
the dielectric structure includes a second dielectric portion between the material of the memory device and the second conductive portion, and the second dielectric portion includes a third thickness greater than each of the first and second thicknesses.

13. The apparatus of claim 12, wherein the second dielectric portion includes a dielectric material having a dielectric constant less than the dielectric constant of the second dielectric material.

14. The apparatus of claim 12, wherein the second dielectric portion includes a dielectric material having a same dielectric constant as the first dielectric material.

15. The apparatus of claim 12, wherein the first dielectric material includes silicon dioxide.

16. The apparatus of claim 12, wherein the second dielectric portion includes silicon dioxide.

17. The apparatus of claim 12, wherein:
the first conductive portion includes titanium nitride; and
the second conductive portion includes polysilicon.

18. The apparatus of claim 12, wherein:
the second dielectric material contacts the second dielectric portion at a first interface;
the first conductive portion contacts the second conductive portion at a second interface; and
the first interface is at a level below a level of the second interface.

19. The apparatus of claim 12, wherein the conductive structure is part of a word line for a memory cell of the memory device.

20. The apparatus of claim 12, wherein the memory device includes a semiconductor material, and wherein:
the semiconductor material includes a first portion on a first side of the conductive structure;
the semiconductor material includes a second portion on a second side the conductive structure; and
the first and second portions form source and drain, respectively, of a transistor, and the conductive structure forms a control gate of the transistor.

21. The apparatus of claim 20, wherein one of the first and second semiconductor portions is coupled to a capacitor of the apparatus.

22. The apparatus of claim 20, wherein one of the first and second semiconductor portions is coupled to data line of the apparatus.

23. A method comprising:
forming a recess in a semiconductor material of a memory device;
forming a dielectric structure in the recess; and
forming a conductive structure for an access line for memory cells of the memory device, such that the conductive structure includes a first conductive portion formed in the recess and a second conductive portion in the recess and over the first portion, and wherein:
the first conductive portion is separated from the semiconductor material by a first portion of the dielectric structure, the first portion of the dielectric structure including first dielectric material and a second dielectric material, and the second conductive portion is separated from the semiconductor material by a second portion of the dielectric structure; and
the second dielectric material has a dielectric constant greater than a dielectric constant of silicon dioxide.

24. The method of claim 23, wherein the second portion of the dielectric structure includes a dielectric material having a dielectric constant less than the dielectric constant of the second dielectric material.

25. The method of claim 23, wherein the second portion of the dielectric structure includes silicon dioxide between and contacting the semiconductor material and the second conductive portion of the conductive structure.

26. The method of claim 23, wherein forming the dielectric structure includes forming a dielectric material in the second portion of the dielectric structure to have a thickness greater than a thickness of each of the first and second dielectric materials.

27. The method of claim 23, wherein the first and second conductive portions include different conductive materials.

28. A method comprising:
forming a recess in a semiconductor material;
forming a first dielectric material on sidewalls and a bottom of the recess;
forming a second dielectric material in the recess and over a first portion of the first dielectric material, wherein the second dielectric material has a dielectric constant greater than a dielectric constant of silicon dioxide;
forming a first conductive material in the recess and over the second dielectric material, such that first conductive material is separated from the semiconductor material by the first portion of the first dielectric material and the second dielectric material;
forming a third dielectric material in the recess on a second portion of the first dielectric material; and
forming a second conductive material in the recess and over the first conductive portion, such that second conductive material is separated from the semiconductor material by the second portion of the first dielectric material and the third dielectric material.

29. The method of claim 28, wherein the first and third dielectric materials include a same material.

30. The method of claim 28, wherein the third dielectric material includes a thickness greater than a thickness of each of the first and second dielectric materials.

31. The method of claim 28, wherein the first and second conductive materials include different conductive materials.

32. The method of claim 28, wherein the first and second conductive materials are part of a word line of a memory device.
